(19) United States
(12) Patent Application Publication
(10) Pub. No.: US 2020/0192136 A1
(43) Pub. Date: Jun. 18, 2020

(54) ARRAY SUBSTRATE, METHOD FOR MANUFACTURING THE SAME, AND LIQUID CRYSTAL DISPLAY PANEL

(71) Applicant: Shenzhen China Star Opoelectriconics Semiconductor Display Technology.,Ltd, Shenzhen, Guangdong (CN)

(72) Inventors: Yuanyang MA, Shenzhen, Guangdong (CN); Lixuan CHEN, Shenzhen, Guangdong (CN); Xulin LIN, Shenzhen, Guangdong (CN)

(21) Appl. No.: 16/337,797

(22) PCT Filed: Nov. 19, 2018
(86) PCT No.: PCT/CN2018/116143

§ 371 Date: Mar. 28, 2019

(30) Foreign Application Priority Data
Oct. 15, 2018 (CN) 201811195510.3

(51) Int. Cl. G02F 1/1339; C23C 16/04

(52) U.S. Cl. CPC G02F 1/1339; G02F 2001/13398; C23C 16/042

(57) ABSTRACT

The present invention provides a method for manufacturing an array substrate, including a metal oxidation process after a step of removing a photoresist layer and before a step of forming an insulating film by a CVD device to form metallic oxides on side surfaces of patterned metal lines. Oxidation of metals is completed by the CVD device, thereby reducing the leakage of light to improve the contrast of an LCD panel, and improving the production efficiency and productivity of the LCD panel.

### BACKGROUND OF THE INVENTION

### 1. Field of the Invention

The present invention relates to a display technology field, and more particularly to a liquid crystal display and a method for manufacturing an array substrate.

### 2. Description of the Prior Art

In life, an LCD (Liquid Crystal Display) device has become the most commonly used display device. Wherein, the contrast of an LCD panel is an important index for measuring the optical performance of the LCD device. But there are arc-shaped cross metal structures in the LCD panel, which can lead to light leakage and thus reduce the contrast of the LCD panel. In the prior art, the leak light can be effectively reduced and the contrast can be improved by directly canceling vertical metal lines, moving horizontal metal lines to the bottom of a black grid area outside a sub-pixel display area, designing pixel electrodes to be in horizontal and vertical directions, and other ways which can change pixel structures. But for the large size, high-resolution high-order LCD displays, in order to ensure the charging efficiency and the relatively adequate storage capacitance, the metal structure should not be removed to improve the light leakage characteristic of the LCD panel.

In a word, some high-resolution LCD panels that must have metal structures have the problem of leaking light, so the existing technology has room for improvement.

### BRIEF SUMMARY OF THE INVENTION

The technical problem to be solved in the present invention is to providing a method for manufacturing an array substrate to improve the leakage of light in a high-resolution LCD panel with metal structures.

In order to solve the above technical problem, the present invention provides a method for manufacturing an array substrate, comprising the following steps of:

(S101) a coating process for coating a metal film on one surface of a glass substrate;

(S102) a coating process for coating a photoresist layer on the metal film;

(S103) an exposure process for selectively exposing the glass substrate coated with the photoresist layer;

(S104) a developing process for dissolving the exposed photoresist layer;

(S105) an etching process for etching the metal film not covered by the photoresist layer to form patterned metal lines; and

(S106) an oxidation process for forming metallic oxides on side surfaces of the patterned metal lines by an oxidation reaction.

In one embodiment, the step (S106) includes the following steps of:

(S10611) a photoresist removal process for removing the photoresist layer on the glass substrate; and

(S10612) a metal oxidation process for performing an oxidation treatment of the patterned metal lines on the glass substrate by a CVD device.

The metal oxidation process is placing the glass substrate in a receiving cavity of the CVD device and injecting oxygen or ozone into the receiving cavity, and an oxidation time is 80˜120 seconds.

In the other embodiment, the step (S106) includes the following steps of:

(S10621) a metal oxidation process for performing an oxidation treatment of the patterned metal lines on the glass substrate;

(S10622) a photoresist removal process for removing the photoresist layer on the glass substrate.

In the present invention, the metal oxidation process can be completed by many ways.

One way is injecting oxygen, ozone, or clean and dry compressed air into a receiving cavity accommodating the glass substrate, and keeping a temperature in the receiving cavity below 150° C. and a gas flow rate below 3000 milliliters per minute.

And an oxidation time does not exceed 240 seconds in the metal oxidation process.

Another way is oxidizing the patterned metal lines on the glass substrate by a dilution solution of a strong oxidant.

In the present invention, the diluted solution of the strong oxidant is uniformly coated on the side surfaces of the patterned metal lines by brushing.

The present invention also provides an array substrate, which is prepared by the method as described above.

The present invention further provides a liquid crystal display panel comprising an array substrate as described above.

In addition, the present invention provides another method for manufacturing an array substrate, comprising the following steps of:

(S101) a coating process for coating a metal film on one surface of a glass substrate;

(S102) a coating process for coating a photoresist layer on the metal film;

(S103) an exposure process for selectively exposing the glass substrate coated with the photoresist layer;

(S104) a developing process for dissolving the exposed photoresist layer;

(S105) an etching process for etching the metal film not covered by the photoresist layer to form patterned metal lines; and

(S106) an oxidation process for forming metallic oxides on side surfaces of the patterned metal lines by an oxidation reaction.

Wherein after performing the developing process and before performing the etching process, the method further includes a step of baking the glass substrate to make the unexposed photoresist layer more firmly adhere to the metal film.

In one embodiment, the step (S106) includes the following steps of:

(S10611) a photoresist removal process for removing the photoresist layer on the glass substrate; and

(S10612) a metal oxidation process for performing an oxidation treatment of the patterned metal lines on the glass substrate by a CVD device.

The metal oxidation process is placing the glass substrate in a receiving cavity of the CVD device and injecting oxygen or ozone into the receiving cavity, and an oxidation time is 80˜120 seconds.

In the other embodiment, the step (S106) includes the following steps of:

(S10621) a metal oxidation process for performing an oxidation treatment of the patterned metal lines on the glass substrate;

(S10622) a photoresist removal process for removing the photoresist layer on the glass substrate.

In the present invention, the metal oxidation process can be completed by many ways.

One way is injecting oxygen, ozone, or clean and dry compressed air into a receiving cavity accommodating the glass substrate, and keeping a temperature in the receiving cavity below 150° C. and a gas flow rate below 3000 milliliters per minute.

And an oxidation time does not exceed 240 seconds in the metal oxidation process.

Another way is oxidizing the patterned metal lines on the glass substrate by a dilution solution of a strong oxidant.

In the present invention, the diluted solution of the strong oxidant is uniformly coated on the side surfaces of the patterned metal lines by brushing.

The beneficial effects of the present invention are as follows. The method for manufacturing the array substrate includes the oxidation process. In one embodiment, the metal oxidation process takes place after the step of removing the photoresist layer and before the step of forming the insulating films by the CVD device, and oxidation of metals is completed by the CVD device, so the metal lines can be fast oxidized and the metal oxidation process will not disrupt a normal order of manufacturing the array substrate. Hence, the method for manufacturing the array substrate not only can reduce the leakage of light to improve the contrast of the LCD panel, but also can improve the production efficiency and productivity of the LCD panel. In the other embodiment, the metal oxidation process takes place after the step of etching the metal film and before the step of removing the photoresist layer. The metal oxidation process is performed before removing the photoresist layer, so the upper surface of the metal lines can not be damaged because of being covered by the photoresist layer. Therefore, the method for manufacturing the array substrate not only can reduce the leakage of light to improve the contrast of the LCD panel, but also can ensure the conductivity of the metal lines.

The array substrate manufactured by the above method of the present invention and the LCD panel including the array substrate not only can retain arc-shaped cross metal structures for ensuring charging efficiency and storage capacitance, but also can reduce the leakage of light by the oxidation of the metal lines to improve the contrast of the LCD panel.

### BRIEF DESCRIPTION OF THE DRAWINGS

For more clearly understanding above content of the present invention, the following text will briefly introduce the accompanying drawings used in the preferred embodiment of the present invention. It is obvious that the accompanying drawings in the following description are only some embodiments of the present invention. For the technical personnel of the field, other drawings can also be obtained from these drawings without paying creative work.

FIG. 1 is a flowchart showing part of a method for manufacturing an array substrate in one embodiment of the present invention;

FIG. 2 is a flowchart of one embodiment of an oxidation process in the method for manufacturing the array substrate in one embodiment of the present invention; and

FIG. 3 is a flowchart of the other embodiment of the oxidation process in the method for manufacturing the array substrate in one embodiment of the present invention.

### DETAILED DESCRIPTION OF THE PREFERRED EMBODIMENTS

The following text will clearly and completely describe embodiments of the present invention with reference to the accompanying drawings. Obviously, the described embodiments are only part of the embodiments of the invention, not all of the embodiments. Based on the embodiments of the present invention, all of the other embodiments acquired by those skilled in the art without creative labor will fall within the scope of the present invention.

In the following description of the present invention, it should be noted that terminology, such as “upper”, “lower”, “inside”, “outside”, “surface” etc., are used with reference to the orientation or position of the accompanying drawings. They are intended to better and more clearly describe and understand the present invention, but not intended to instruct or imply that the referred device or element has to be of a certain direction, or operated or constructed along a certain direction. Therefore, these terms cannot be interpreted as limitations to the present invention.

In addition, it should be noted that the accompanying drawings provide only the structures and/or steps that are closely related to the present invention, and omit some details that are not relevant to the present invention, in order to simplify the drawings and make the points of invention clear at a glance. Namely, the device and/or method in practice are not exactly the same as the drawings, so the drawings do not act as the limitations of device and/or method.

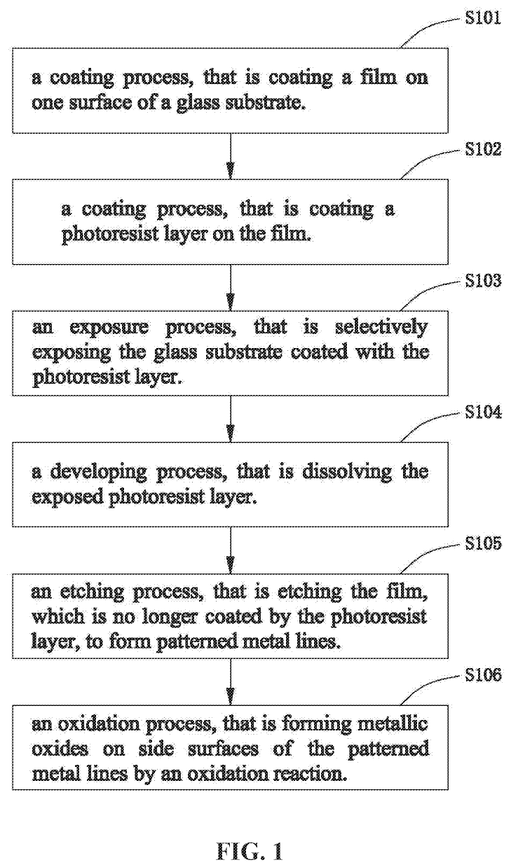

Referring to FIG. 1, FIG. 1 is a flowchart showing part of a method for manufacturing an array substrate in one embodiment of the present invention. In the embodiment, the method includes following steps.

A step S101 is a coating process, that is coating a metal film on one surface of a glass substrate.

It should be noted that many films can be coated on the glass substrate in turn. Depending on coating materials, different coating methods will be adopted. Generally speaking, there are two kinds of coating methods: PVD and CVD. The PVD is an abbreviation for Physical Vapor Deposition. It means that under a vacuum condition, using a discharge technology of a low voltage and a high current arc, a target material is evaporated and the evaporated target material and gas are ionized by gas discharge, and the evaporated target material and its reaction products are deposited on a workpiece by the acceleration of an electric field. The CVD is an abbreviation for Chemical Vapor Deposition. It refers that the solid films are prepared by chemical reaction of gas containing target elements.

It is necessary to understand that, a first, a third and a fifth films on the glass substrate are used as scanning lines, signal lines and electrode plates respectively. All the coatings are metal, and the PVD coating method is used here. A second and a fourth films on the glass substrate both have the function of insulating films, and the CVD coating method is used to form the insulating films.

Since this method for manufacturing the array substrate includes an oxidation step of metal wires in the middle and later stages, the steps described herein are all for the metal film.

A step S102 is a coating process, that is coating a photoresist layer on the film.

It is necessary to rinse the glass substrate with ionized water before coating the photoresist layer. The photoresist layer can be photoresist liquid or photoresist glue. Both the photoresist liquid and the photoresist glue refer to a corrosion resistant film material. The solubility of the corrosion resistant film material can change through an ultraviolet light and other lights or radiation. The corrosion resistant film material is a key material in a photolithography process. The corrosion resistant film material is used here to assist in forming fine patterns on the glass substrate. After coating the photoresist layer, it needs baking for a period of time to volatilize part of the photoresist liquid and increase the adhesion between the photoresist layer and the film.

A step S103 is an exposure process, that is selectively exposing the glass substrate coated with the photoresist layer.

A specific method is to irradiate the glass substrate coated with the photoresist layer through the ultraviolet light passing through a mask. The mask is made according to a corresponding circuit diagram. An irradiation time is determined according to the solidification state of the photoresist layer. The color of the unexposed photoresist layer is different from that of the exposed one.

A step S104 is a developing process, that is dissolving the exposed photoresist layer.

Wherein it is necessary to wait until the photoresist layer of the glass substrate is fixed, and then dissolve the exposed photoresist layer with a developing solution to obtain a metal pattern. This can ensure that the metal pattern is not damaged and is accurate, and the exposed photoresist layer is washed away with ionic water.

It should be noted that after development, the glass substrate needs to be baked for making the unexposed photoresist layer more firmly adhere to the film, so as to ensure that the metal pattern under the unexposed photoresist layer can be retained later.

A step S105 is an etching process, that is etching the film, which is no longer coated by the photoresist layer, to form patterned metal lines.

Wherein an etching solution used here should be acid.

A step S106 is an oxidation process, that is forming metallic oxides on side surfaces of the patterned metal lines by an oxidation reaction. The oxidation process may be performed by two embodiments.

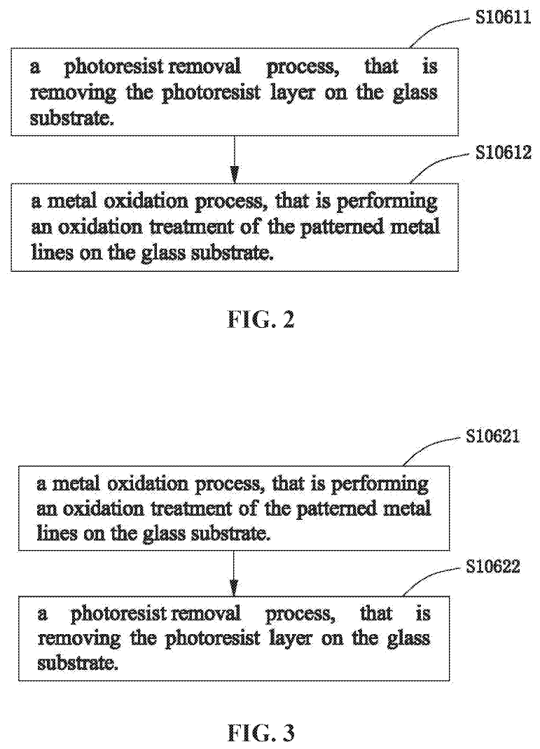

FIG. 2 is a flowchart of one embodiment of the oxidation process in the method for manufacturing the array substrate. In the one embodiment, the oxidation process includes at least two following steps, including a step S10611 and a step S10612.

The step S10611 is a photoresist removal process, that is removing the photoresist layer on the glass substrate.

Wherein, the photoresist layer can be removed with a special photoresist removal solution. After the photoresist layer is stripped, the reacted or remained photoresist can be washed away with an organic solution to ensure that the patterned glass substrate is clean.

The step S10612 is a metal oxidation process, that is performing an oxidation treatment of the patterned metal lines on the glass substrate by a CVD device.

It can be understood that the metal oxidation process is directed at the metal films. It has been mentioned that the first, third and fifth films on the glass substrate are all the metal films and are all depending on the PVD coating method. The second and fourth films on the glass substrate are all the insulating films and are all depending on the CVD coating method. That is to say, after the photoresist layer is removed, the insulating films will be formed by the CVD coating method.

In the one embodiment, the metal oxidation process takes place after the step of removing the photoresist layer and before the step of forming the insulating films by the CVD device. Specifically, before forming the insulating films by the CVD, an oxidizing gas will be introduced into a cavity of CVD equipment to oxidize the metal film. Wherein the oxidizing gas is oxygen, ozone and their mixed gas, and can also be other oxidizing gases or various oxidizing gas mixtures. In addition, an oxidation time is 80˜120 seconds to avoid excessive oxidation of metals. During the metal oxidation process, an oxidation pressure and a frequency of the applied AC voltage need not be specified, and can be applied according to the requirements of subsequent forming the insulating films using the CVD. Namely, the final goal of setting the oxidation pressure and the frequency of the applied AC voltage is to facilitate the formation of the insulation films in the later CVD stage.

It can be seen that, the present invention does not affect the normal array process at all, and the oxidation speed of the CVD equipment is fast. Therefore, the present invention can reduce depolarization, reduce light leakage and even improve the contrast of display, and improve the production efficiency and productivity of an LCD panel.

FIG. 3 is a flowchart of the other embodiment of the oxidation process in the method for manufacturing the array substrate. In the other embodiment, the oxidation process includes at least two following steps, including a step S10621 and a step S10622.

The step S10621 is a metal oxidation process, that is performing an oxidation treatment of the patterned metal lines on the glass substrate.

The step S10622 is a photoresist removal process, that is removing the photoresist layer on the glass substrate.

Wherein considerations of removing the photoresist layer are the same as those in the one embodiment of the oxidation process mentioned above.

It can be understood that the metal oxidation process is directed at the metal films. In the other embodiment, the metal oxidation process is performed after the step of etching the metal film and before the step of removing the photoresist layer, so the photoresist layer covered on an upper surface of the metal film can protect the upper surface of the metal film and ensure the conductivity of the metal lines. Moreover, the metal oxidation process may be performed by four embodiments.

### Embodiment 1

Oxygen is injected into a receiving cavity accommodating the glass substrate. A temperature in the receiving cavity is kept below 150° C. and a gas flow rate is below 3000 milliliters per minute.

### Embodiment 2

Ozone is injected into a receiving cavity accommodating the glass substrate. A temperature in the receiving cavity is kept below 150° C. and a gas flow rate is below 3000 milliliters per minute.

### Embodiment 3

Clean and dry compressed air is injected into a receiving cavity accommodating the glass substrate. A temperature in the receiving cavity is kept below 150° C. and a gas flow rate is below 3000 milliliters per minute.

It should be noted that the receiving cavity of the above three embodiments can be any container capable of providing the above oxidizing environment. In addition to the above three gases injected into the receiving cavity, the injected gas can also be other oxidizing gases or a mixture of oxidizing gases. And, in the above three embodiments, oxidation time can not exceed 240 seconds to avoid excessive oxidation of metals.

### Embodiment 4

The patterned metal lines on the glass substrate are oxidized by a dilution solution of a strong oxidant.

Wherein, the strong oxidant can be hydrogen peroxide or other strong oxidizing liquids. The diluted solution of the strong oxidant can be uniformly coated on the side surfaces of the patterned metal lines by a brushing way, and can also be uniformly dripped on the side surfaces of the patterned metal lines by a finer tube.

It should be noted that, when the patterned metal lines on the glass substrate are oxidized by the dilution solution of the strong oxidant, oxidation is produced on the side surfaces of the patterned metal lines without causing corrosion of the metal lines. Oxidation of non-metallic layers should be minimized. Moreover, it should also be noted that the amount of the solution applied on the side surfaces of the metal lines and the time of the oxidation are depending on the oxidation of the metal lines, and it is important not to cause the corrosion of the metal lines.

Accordingly, the present invention not only can reduce the leakage of light produced by metal lines so as to improve the contrast of the display, but also can not cause damage to the upper surface of the metal lines during the oxidation treatment, thereby ensuring the electric conductivity of the metal lines.

The beneficial effects of the present invention are as follows. The method for manufacturing the array substrate includes the oxidation process. In one embodiment, the metal oxidation process takes place after the step of removing the photoresist layer and before the step of forming the insulating films by the CVD device, and oxidation of metals is completed by the CVD device, so the metal lines can be fast oxidized and the metal oxidation process will not disrupt a normal order of manufacturing the array substrate. Hence, the method for manufacturing the array substrate not only can reduce the leakage of light to improve the contrast of the LCD panel, but also can improve the production efficiency and productivity of the LCD panel. In the other embodiment, the metal oxidation process takes place after the step of etching the metal film and before the step of removing the photoresist layer. The metal oxidation process is performed before removing the photoresist layer, so the upper surface of the metal lines can not be damaged because of being covered by the photoresist layer. Therefore, the method for manufacturing the array substrate not only can reduce the leakage of light to improve the contrast of the LCD panel, but also can ensure the conductivity of the metal lines.

The array substrate manufactured by the above method of the present invention and the LCD panel including the array substrate not only can retain arc-shaped cross metal structures for ensuring charging efficiency and storage capacitance, but also can reduce the leakage of light by the oxidation of the metal lines to improve the contrast of the LCD panel.

The method for manufacturing the array substrate provided in the embodiment of the present invention is described in detail above. The principle and implementation of the present invention are described with specific examples in the text. The explanation of the above embodiment is only used to help understand the technical scheme and the core idea of the present invention. For those of ordinary skill in the art, it should be understood that the technical solutions of all the above embodiments can be modified, or some of the technical features can be replaced. But these modifications and substitutions do not divert the essence of the corresponding technical solutions from the scope of the technical solutions of the embodiments of the present invention.

1. A method for manufacturing an array substrate, comprising the following steps of:
(S101) a coating process for coating a metal film on one surface of a glass substrate;
(S102) a coating process for coating a photoresist layer on the metal film;
(S103) an exposure process for selectively exposing the glass substrate coated with the photoresist layer;
(S104) a developing process for dissolving the exposed photoresist layer;
(S105) an etching process for etching the metal film not covered by the photoresist layer to form patterned metal lines; and
(S106) an oxidation process for forming metallic oxides on side surfaces of the patterned metal lines by an oxidation reaction.

2. The method for manufacturing the array substrate as claimed in claim 1, wherein the step (S106) includes the following steps of:
(S10611) a photoresist removal process for removing the photoresist layer on the glass substrate; and
(S10612) a metal oxidation process for performing an oxidation treatment of the patterned metal lines on the glass substrate by a CVD device.

3. The method for manufacturing the array substrate as claimed in claim 2, wherein the metal oxidation process is placing the glass substrate in a receiving cavity of the CVD device and injecting oxygen or ozone into the receiving cavity, and an oxidation time is 80˜120 seconds.

4. The method for manufacturing the array substrate as claimed in claim 1, wherein the step (S106) includes the following steps of:
(S10621) a metal oxidation process for performing an oxidation treatment of the patterned metal lines on the glass substrate;
(S10622) a photoresist removal process for removing the photoresist layer on the glass substrate.

5. The method for manufacturing the array substrate as claimed in claim 4, wherein the metal oxidation process is injecting oxygen, ozone, or clean and dry compressed air into a receiving cavity accommodating the glass substrate, and keeping a temperature in the receiving cavity below 150° C. and a gas flow rate below 3000 milliliters per minute.

6. The method for manufacturing the array substrate as claimed in claim 5, wherein an oxidation time does not exceed 240 seconds in the metal oxidation process.

7. The method for manufacturing the array substrate as claimed in claim 4, wherein the patterned metal lines are oxidized by a dilution solution of a strong oxidant.

8. The method for manufacturing the array substrate as claimed in claim 7, wherein the diluted solution of the strong oxidant is uniformly coated on the side surfaces of the patterned metal lines by brushing.

9. A method for manufacturing an array substrate, comprising the following steps of:
(S101) a coating process for coating a metal film on one surface of a glass substrate;
(S102) a coating process for coating a photoresist layer on the metal film;
(S103) an exposure process for selectively exposing the glass substrate coated with the photoresist layer;
(S104) a developing process for dissolving the exposed photoresist layer;
(S105) an etching process for etching the metal film not covered by the photoresist layer to form patterned metal lines; and
(S106) an oxidation process for forming metallic oxides on side surfaces of the patterned metal lines by an oxidation reaction;
wherein after performing the developing process and before performing the etching process, the method further includes a step of baking the glass substrate to make the unexposed photoresist layer more firmly adhere to the metal film.

10. The method for manufacturing the array substrate as claimed in claim 9, wherein the step (S106) includes the following steps of:
(S10611) a photoresist removal process for removing the photoresist layer on the glass substrate; and
(S10612) a metal oxidation process for performing an oxidation treatment of the patterned metal lines on the glass substrate by a CVD device.

11. The method for manufacturing the array substrate as claimed in claim 10, wherein the metal oxidation process is placing the glass substrate in a receiving cavity of the CVD device and injecting oxygen or ozone into the receiving cavity, and an oxidation time is 80˜120 seconds.

12. The method for manufacturing the array substrate as claimed in claim 9, wherein the step (S106) includes the following steps of:
(S10621) a metal oxidation process for performing an oxidation treatment of the patterned metal lines on the glass substrate;
(S10622) a photoresist removal process for removing the photoresist layer on the glass substrate.

13. The method for manufacturing the array substrate as claimed in claim 11, wherein the metal oxidation process is injecting oxygen, ozone, or clean and dry compressed air into a receiving cavity accommodating the glass substrate, and keeping a temperature in the receiving cavity below 150° C. and a gas flow rate below 3000 milliliters per minute.

14. The method for manufacturing the array substrate as claimed in claim 12, wherein an oxidation time does not exceed 240 seconds in the metal oxidation process.

15. The method for manufacturing the array substrate as claimed in claim 11, wherein the patterned metal lines are oxidized by a dilution solution of a strong oxidant.

16. The method for manufacturing the array substrate as claimed in claim 14, wherein the diluted solution of the strong oxidant is uniformly coated on the side surfaces of the patterned metal lines by brushing.

17. An array substrate, which is prepared by a method as claimed in claim 1.

18. A liquid crystal display panel comprising an array substrate as claimed in claim 9.
